(19) United States
(12) Patent Application Publication
(10) Pub. No.: US 2014/0183570 A1
(43) Pub. Date: Jul. 3, 2014

(54) Illumination Apparatuses

(71) Applicant: Evergrand Holdings Limited, British Virgin Islands (VG)

(72) Inventor: YU-NUNG SHEN, Taipei (TW)

(73) Assignee: Evergrand Holdings Limited, British Virgin Islands (VG)

(21) Appl. No.: 14/135,819

(22) Filed: Dec. 20, 2013

(30) Foreign Application Priority Data
Dec. 25, 2012 (TW) 101149951

(51) Int. Cl. H01L 33/64

(52) U.S. Cl. CPC H01L 33/647
USPC 257/88

(57) ABSTRACT

The present invention provides an illumination apparatus. The illumination apparatus comprises a body having a lower portion coupled to a standard metallic lamp adaptor and an upper portion; a light source module comprising an LED array of LED chips connected in series, a phosphor powder layer encapsulating the LED chips, and a pair of conductive wires electrically connected to the LED chips for transmitting electric power to the LED chips; and a transparent housing coupled to the upper portion of the body, so that the LED chips are enveloped within the transparent housing.

### PRIORITY CLAIM

This application claims priority to R.O.C. Patent Application No. 101149951 filed Dec. 25, 2012, the entirety of which is incorporated herein by reference.

### BACKGROUND OF THE INVENTION

1. Field of the Invention

The present invention relates to illumination apparatuses.

2. Description of the Prior Art

While the incandescent bulb used to be the main type of illumination apparatus available in the technical field of illumination applications, it has been gradually replaced by light-emitting diode (LED) light bulb, as the latter shows much higher energy-saving property and is much more friendly to the environment. However, the LED bulb now available in the market still cannot satisfy all the consumer's demands, as it can only provide light emission over 180 degree and has relatively poor brightness and chromaticity compared to the conventional incandescent bulb.

Moreover, the LED bulbs now available in the market normally demonstrate a poor heat dissipation capability, resulting in a reduced service life.

In order to overcome the drawbacks described above, the inventor has devised high brightness illumination apparatuses as disclosed herein.

### SUMMARY OF THE INVENTION

According to an aspect of the invention, a light-emitting diode device is provided, which comprises:

According to an aspect of the present invention, an illumination apparatus is provided. The illumination apparatus comprises: a body having a base, a thermal conductive portion extending upwardly from top of the base, a threaded portion extending downwardly from bottom of the base, and a standard metallic lamp adaptor threaded onto the threaded portion; at least one metal rod extending upwardly from the base of the body in a manner penetrating through the thermal conductive portion, so that the at least one metal rod has an end portion protruding outwardly from top of the thermal conductive portion and the end portion is cuboid-shaped thereby defining five generally planar mounting surfaces; a light source module comprising five support plates, each being mounted on a corresponding one of the mounting surfaces of the at least one metal rod, and a plurality of LED chip arrays operatively mounted on the support plates corresponding thereto; a transparent housing couple to the base of the body, so that the light source module and the thermal conductive portion are enveloped within the transparent housing.

According to another aspect of the present invention, an illumination apparatus is provided. The illumination apparatus comprises: a body having a base, a thermal conductive portion extending upwardly from top of the base, a threaded portion extending downwardly from bottom of the base, and a standard metallic lamp adaptor threaded onto the threaded portion; at least one metal rod extending upwardly from the base of the body in a manner penetrating through the thermal conductive portion, so that the at least one metal rod has an end portion protruding outwardly from top of the thermal conductive portion and formed with a via hole; a light source module comprising a support plate having high heat dissipation capability and made of transparent material with high heat dissipation capability, the support plate having a chip-mounting surface and mounted at the end portion of the at least one metal rod where the via hole is formed; an LED chip array of multiple LED chips operatively mounted on the chip-mounting surface of the support plate and exposed through the via hole; and a transparent layer made of insulative transparent material doped with phosphor powder and encapsulating the end portion of the at least one metal rod, so that the chip-mounting surface of the support plate and the back surface opposite to the chip-mounting surface are both covered by the transparent layer, making the LED chips embedded within the transparent layer; and a transparent housing couple to the base of the body, so that the light source module and the thermal conductive portion are enveloped within the transparent housing.

According to still another aspect of the present invention, an illumination apparatus is provided. The illumination apparatus comprises: a body having a base, a thermal conductive portion extending upwardly from top of the base, a threaded portion extending downwardly from bottom of the base, and a standard metallic lamp adaptor threaded onto the threaded portion; a metal rod extending upwardly from the base of the body in a manner penetrating through the thermal conductive portion, so that the metal rod has an end portion protruding outwardly from the thermal conductive portion; a light source module comprising a support plate having a chip-mounting surface and carried by the metal rod, and an LED chip array operatively mounted on the chip-mounting surface of the support plate; and a transparent housing couple to the base of the body, so that the light source module and the thermal conductive portion are enveloped within the transparent housing.

According to still another aspect of the present invention, an illumination apparatus is provided. The illumination apparatus comprises: a body having a base, a thermal conductive portion extending upwardly from top of the base, a threaded portion extending downwardly from bottom of the base, and a standard metallic lamp adaptor threaded onto the threaded portion; a metal rod extending upwardly from the base of the body in a manner penetrating through the thermal conductive portion, so that the metal rod has an end portion protruding outwardly from the thermal conductive portion; a light source module comprising an LED chip array configured in the form of a predetermined matrix during wafer dicing process and operatively mounted at top of the metal rod; and a transparent housing couple to the base of the body, so that the light source module and the thermal conductive portion are enveloped within the transparent housing.

According to still another aspect of the present invention, an illumination apparatus is provided. The illumination apparatus comprises: a body having a base, a thermal conductive portion extending upwardly from top of the base, a threaded portion extending downwardly from bottom of the base, and a standard metallic lamp adaptor threaded onto the threaded portion; a cooling device comprising a radially arranged air inlet port formed in the base of the body and connected to the ambient, a radially arranged air outlet port formed in the base of the body and connected to the ambient, and an axial piston passage formed in the base of the body and arranged in fluid communication with the inlet port and the outlet port, the cooling device further comprising an axially movable piston disposed within the axial piston passage, a through hole formed in the thermal conductive portion of the body, and a shaft disposed within the axial piston passage and adapted for guiding the piston for reciprocal movement along the axial piston passage; a light source module comprising a metal rod having one end portion protruding outwardly from the thermal conductive portion of the body and the other end portion disposed within the passage and remote from the shaft, and an LED chip array operatively mounted on the one end portion of the metal rod that protrudes outwardly from the thermal conductive portion of the body; and a transparent housing couple to the base of the body, so that the light source module and the thermal conductive portion are enveloped within the transparent housing, whereby when the LED chip array is under operation and the piston is located at a standby position close to the other end portion of the metal rod, the heat generated by the LED array is transferred into the passage through the metal rod, causing hot air to push the piston to move along the passage towards where the shaft is fixed, and ambient cold air enters the body through the air inlet port and hot air in the housing enters the body via the through hole, and wherein the air in the body consequently passes through the piston and disperses to the ambient environment via the air outlet port as a vent located on top of the piston is opened by the shaft, and the piston returns back to the standby position as the gas departs from the body.

According to still another aspect of the present invention, an illumination apparatus is provided. The illumination apparatus comprises: a body having a base, a thermal conductive portion extending upwardly from top of the base, a threaded portion extending downwardly from bottom of the base, and a standard metallic lamp adaptor threaded onto the threaded portion; a cooling device comprising a radially arranged air inlet port formed in the base of the body and connected to the ambient, a radially arranged air outlet port formed in the base of the body and connected to the ambient, and an axial piston passage formed in the base of the body and arranged in fluid communication with the inlet port and the outlet port, the cooling device further comprising an cooling fan disposed within the passage, and a through hole formed in the thermal conductive portion of the body; an LED chip array operatively mounted on an end portion of the metal rod that protrudes outwardly from the thermal conductive portion of the body; and a transparent housing couple to the base of the body, so that the light source module and the thermal conductive portion are enveloped within the transparent housing, whereby when the fan is under operation, ambient cold air enters the body through the air inlet port and some of the cold air flows into the housing via the through hole and then enters the passage through a via hole located on another side of the thermal conductive portion and disperses to the ambient through the air outlet port.

According to still another aspect of the present invention, an illumination apparatus is provided. The illumination apparatus comprises: a body having a base, a thermal conductive portion extending upwardly from top of the base, a threaded portion extending downwardly from bottom of the base, and a standard metallic lamp adaptor threaded onto the threaded portion; a light source module comprising a flexible substrate and a plurality of LED chips operatively mounted on the substrate, wherein the flexible substrate is attached to the thermal conductive portion of the body, so that each and every surface of an end portion of the thermal conductive portion is mounted with an LED chip; and a transparent housing couple to the base of the body, so that the light source module and the thermal conductive portion are enveloped within the transparent housing.

According to still another aspect of the present invention, an illumination apparatus is provided. The illumination apparatus comprises: a body having a lower portion coupled to a standard metallic lamp adaptor and an upper portion; a light source module comprising an LED array of LED chips connected in series, a phosphor powder layer encapsulating the LED chips, and a pair of conductive wires electrically connected to the LED chips for transmitting electric power to the LED chips; and a transparent housing coupled to the upper portion of the body, so that the LED chips are enveloped within the transparent housing.

According to still another aspect of the present invention, an illumination apparatus is provided. The illumination apparatus comprises: a body having a lower portion coupled to a standard metallic lamp adaptor and an upper portion; a light source module comprising a transparent substrate having a circuit-mounting surface, on which predetermined circuit traces are formed, a plurality of LED chips operatively mounted on the substrate and electrically connected to the circuit traces corresponding thereto, a phosphor powder layer encapsulating the LED chips and the substrate, and a pair of conductive wires electrically connected to the circuit traces corresponding thereto for transmitting electric power to the LED chips; and a transparent housing coupled to the upper portion of the body, so that the LED chips are enveloped within the transparent housing.

According to still another aspect of the present invention, an illumination apparatus is provided. The illumination apparatus comprises: a body; a standard metallic lamp adaptor coupled to the body; a light source module comprising a heat pipe having high thermal and electrical conductivity, a substrate, a plurality of LED chips operatively mounted on the transparent substrate, a phosphor powder layer encapsulating the LED chips, and a pair of conductive wires electrically connected to the LED chips for transmitting electric power to the LED chips, wherein the heat pipe comprises a top portion mounted with the substrate and a bottom portion extending to the adaptor and electrically connected to the power supplying terminal of the adapter, and wherein one conductive wire in the pair of conductive wires is electrically connected to the heat pipe, and the other conductive wire in the pair of conductive wires is electrically connected to the ground terminal of the adaptor; and a transparent housing coupled to the body, so that the LED chips are enveloped within the transparent housing.

### BRIEF DESCRIPTION OF THE DRAWINGS

The above and other objects, features and effects of the invention will become apparent with reference to the following description of the preferred embodiments taken in conjunction with the accompanying drawings, in which:

FIGS. 1A to 1C are schematic diagrams of the illumination apparatus according to the first preferred embodiment of the invention;

FIG. 1D is a schematic diagram of the illumination apparatus according to the second preferred embodiment of the invention;

FIGS. 2A and 2B are schematic diagrams of the illumination apparatus according to the third preferred embodiment of the invention;

FIGS. 3A and 3B show an alternative example of the light source module used in the illumination apparatus according to the invention;

FIGS. 3C and 3D show an alternative example of the light source module shown in FIGS. 3A and 3B;

FIGS. 4A to 4C are schematic diagrams of the illumination apparatus according to the fourth preferred embodiment of the invention;

FIGS. 5A to 5C are schematic diagrams of the illumination apparatus according to the fifth preferred embodiment of the invention;

FIG. 5D shows an alternative example of the light source module used in the illumination apparatus according to the fifth preferred embodiment of the invention;

FIGS. 6A to 6C are schematic diagrams of the illumination apparatus according to the sixth preferred embodiment of the invention;

FIG. 7 is a schematic diagram of the illumination apparatus according to the seventh preferred embodiment of the invention;

FIGS. 8A and 8B are schematic diagrams of the illumination apparatus according to the eighth preferred embodiment of the invention;

FIGS. 9A and 9B are schematic diagrams of the illumination apparatus according to the ninth preferred embodiment of the invention;

FIG. 9C is a schematic diagram showing an alternative example of the light source module used in the illumination apparatus according to the ninth preferred embodiment of the invention;

FIG. 9D is a schematic diagram showing another alternative example of the light source module used in the illumination apparatus according to the ninth preferred embodiment of the invention;

FIG. 9E is a schematic diagram showing another alternative example of the light source module used in the illumination apparatus according to the ninth preferred embodiment of the invention;

FIGS. 10A and 10B are schematic diagrams of the illumination apparatus according to the tenth preferred embodiment of the invention;

FIGS. 11A and 11B are schematic diagrams showing an alternative example of the illumination apparatus according to the tenth preferred embodiment of the invention;

FIG. 12 is a schematic diagram of the illumination apparatus according to the first preferred embodiment of the invention, in which the transparent housing is configured in a form of a conventional candle-like lamp;

FIGS. 13A and 13B are schematic diagrams showing an alternative example of the illumination apparatus shown in FIGS. 11A and 11B;

FIGS. 14A and 14B are schematic diagrams showing an alternative example of the illumination apparatus shown in FIGS. 11A and 11B;

FIGS. 15A and 15B are schematic diagrams of the illumination apparatus according to the eleventh preferred embodiment of the invention;

FIGS. 16A to 16C are schematic diagrams of the illumination apparatus according to the twelfth preferred embodiment of the invention; and

FIG. 16D is a schematic diagram showing another aspect of the light source module 2 used in the illumination apparatus according to the twelfth preferred embodiment of the invention.

### DETAILED DESCRIPTION OF THE PREFERRED EMBODIMENTS

Before the present invention is described in greater detail, it should be noted that the same or like elements are denoted by the same reference numerals throughout the disclosure. Moreover, the elements shown in the drawings are not illustrated in actual scale, but are expressly illustrated to explain in an intuitive manner the technical feature of the invention disclosed herein.

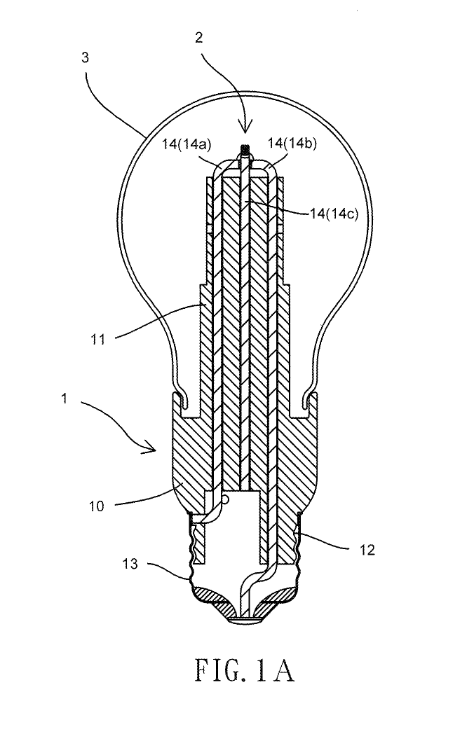

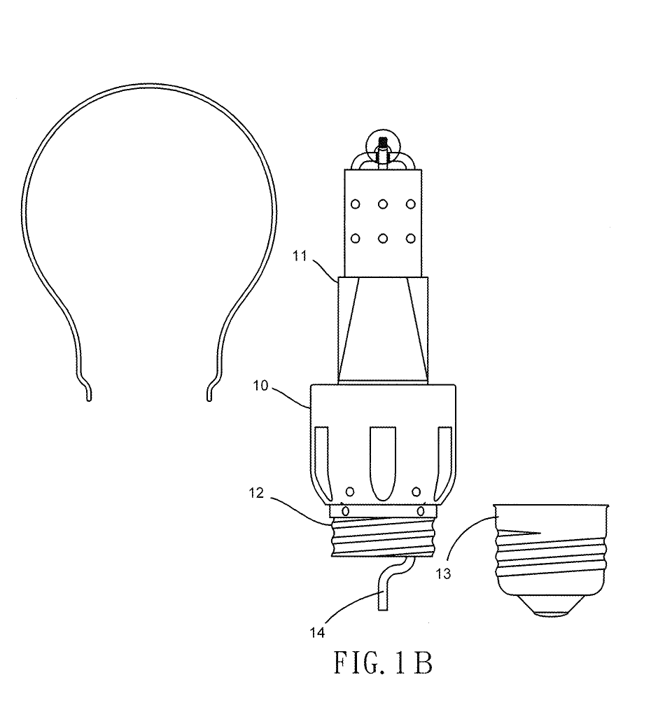

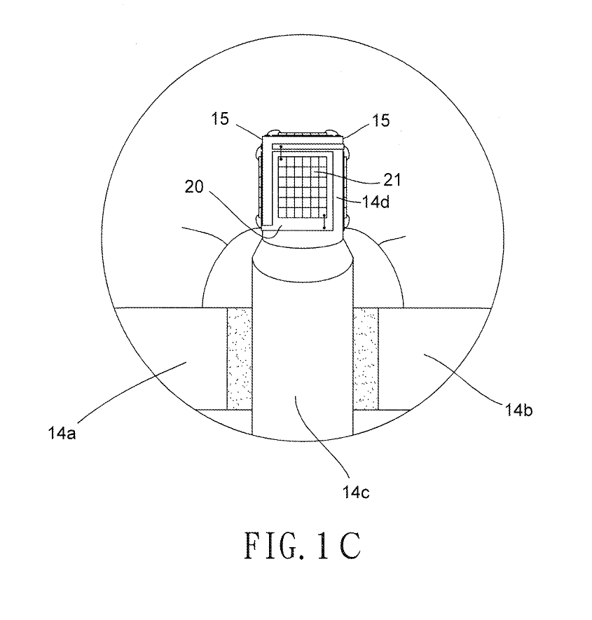

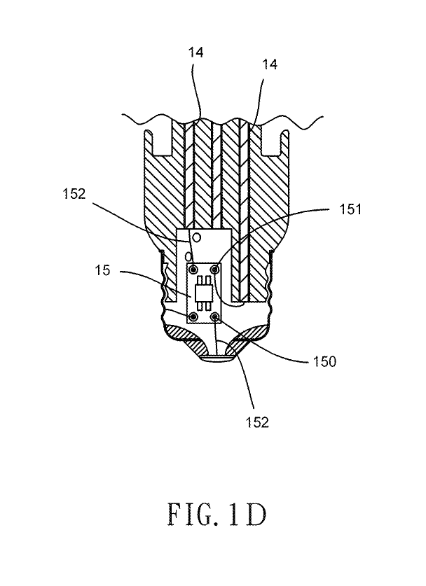

FIGS. 1A to 1C are schematic diagrams of the illumination apparatus according to the first preferred embodiment of the invention.

FIG. 1A is a partial schematic cross-sectional view of the illumination apparatus according to a first preferred embodiment of the invention. As shown in FIG. 1A, the illumination apparatus comprises a body 1, a light source module 2 and a transparent housing 3.

The body 1 is made of material with high heat dissipation capability. According to the embodiment disclosed herein, the body 1 is made of ceramic material. Alternatively, the body 1 can be made of any other material having high heat dissipation capability, such as metallic material, for example, aluminum. Moreover, in the case where the body 1 is made of ceramic material, the ceramic material can be sintered ceramic material doped with other suitable material that may enhance the overall heat dissipation efficiency.

The body 1 includes a base 10, a thermal conductive portion 11 extending upwardly from top of the base 10, a threaded portion 12 extending downwardly from bottom of the base 10, and a standard metallic lamp adaptor 13 threaded onto the threaded portion 12.

Three metal rods 14 (14a, 14b, 14c) with thermal and electrical conductivity are provided, each having an end portion protruding outwardly from top of the thermal conductive portion 11 and an opposite end portion extending downwardly to the base 10. Said opposite ends of the metal rods 14a and 14b further extend from the base 10 to the threaded portion 12 and are electrically connected to the power supplying terminal and the ground terminal of the standard lamp adaptor 13, so that both of heat and electricity may be transferred efficiently via metal parts of the plug and the AC wires (made of copper). As shown in FIG. 1C, the end portion of the metal rod 14c that protrudes outwardly from top of the thermal conductive portion 11 is configured to include five generally planar mounting surfaces 14d.

It should be noted that the three metal rods 14 may be configured in the form of heat pipes having thermal and electrical conductivity.

The light source module 2 comprises at least one support plate 20 and at least one LED chip 21 operatively mounted on the support plate 20.

In the embodiment disclosed herein, the light source module 2 comprises five support plates 20, each having a back surface and a chip-mounting surface opposite to the back surface. The support plates 20 are installed at the end portion of the metal rod 14c in such a manner that the back surfaces of the support plates 20 are attached onto the mounting surfaces 14d.

In the embodiment disclosed herein, the chip-mounting surfaces of the support plates 20 are operatively mounted with an LED chip array, respectively. The LED chip array comprises a plurality of LED chips 21 connected in series and/or in parallel. The LED chips 21 may be white-light LED chips, or blue-light chips coated with a phosphor powder layer. Alternatively, the LED chips 21 comprise a red-light chip, a green-light chip and a blue-light chip arranged in a predetermined manner, thereby emitting white light. In a more preferred embodiment, the LED chips 21 are those described in R.O.C. Patent No. 1364857 or R.O.C. Patent Application No. 098104011.

Each of the LED chips 21 includes a positive electrode and a negative electrode electrically connected to the metal rods 14a, 14b in a direct or indirect manner, so as to receive electric power via the metal rods 14a, 14b. It is apparent to those skilled in the art that the LED chips 21 may emit light having a color other than those described above.

The transparent housing 3 is coupled to the base 10 of the body 1, so that the light source module 2 and the thermal conductive portion 11 are enveloped within the transparent housing 3. The illumination apparatus disclosed herein is produced accordingly. It should be noted that the transparent housing 3 has a dimension similar to the dimension of the transparent housing of the traditional incandescent bulb.

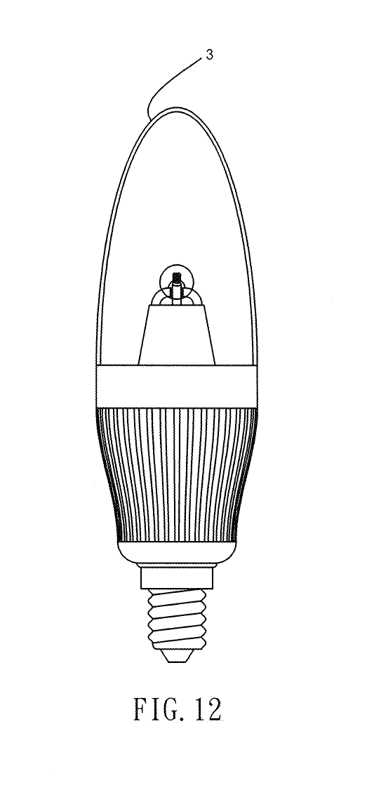

While the transparent housing 3 is shaped into a form of similar to a traditional incandescent bulb, it can be alternatively tailored to meet the specification of another type of conventional lamps, such as a MR-16-, PAR30-, PAR38- and C35-type lamp and a candle-like lamp. According to the embodiment shown in FIG. 12, for example, the transparent housing 3 is configured in a form of a transparent housing of a candle-like lamp.

It should be noted that the LED chip arrays described above each independently comprise a number of LED chips arranged into an M×N matrix, where M and N are independently a natural number of equal to or greater than 1. As such, the LED chips 21 are preferably 6V-480V high-voltage chips connected in series and/or in parallel. Nevertheless, the LED chips 21 can alternatively be high-voltage chips for the applications beyond the voltage range from 6V to 480V.

The LED chip arrays may be directly formed on a wafer and configured into predetermined matrices during the wafer dicing process. Alternatively, the LED chip arrays are each made of separate chips by connecting the chips in series and/or in parallel.

Moreover, the transparent housing 3 may be coated at its inner and/or outer side with a layer of metallic or non-metallic material having high thermal conductivity and high thermal dissipation capability, such as ITO, Al₂O₃ and BnO₃, thereby increasing the overall surface area for heat dissipation to improve heat dissipation efficiency.

FIG. 1D is a schematic diagram of the illumination apparatus according to the second preferred embodiment of the invention.

The embodiment shown in FIG. 1D differs from the first preferred embodiment in that the opposite ends of the metal rods 14 are not electrically connected to the power supplying terminal and the ground terminal of the standard lamp adaptor 13. Instead, the illumination apparatus described herein further comprises a power supply device 15 mounted within the threaded portion 12. The power supply device 15 includes an input electrode 150 electrically connected to the power supplying terminal and the ground terminal of the standard lamp adaptor 13 via a conductive wire 152, and an output electrode 151 electrically connected to the positive and negative electrodes of the LED chips 21 via a conductive wire 152 and the corresponding metal rods 14. Since the electrical connection between the output electrode 151 of the power supply device 15 and the positive and negative electrodes of the LED chips 21 may be established by any method known in the art and is not germane to the distinctive technical features of the apparatus disclosed herein, the details thereof are omitted for brevity.

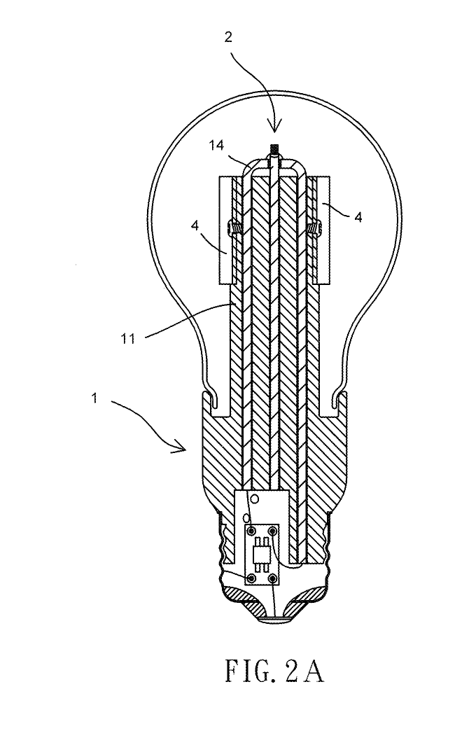

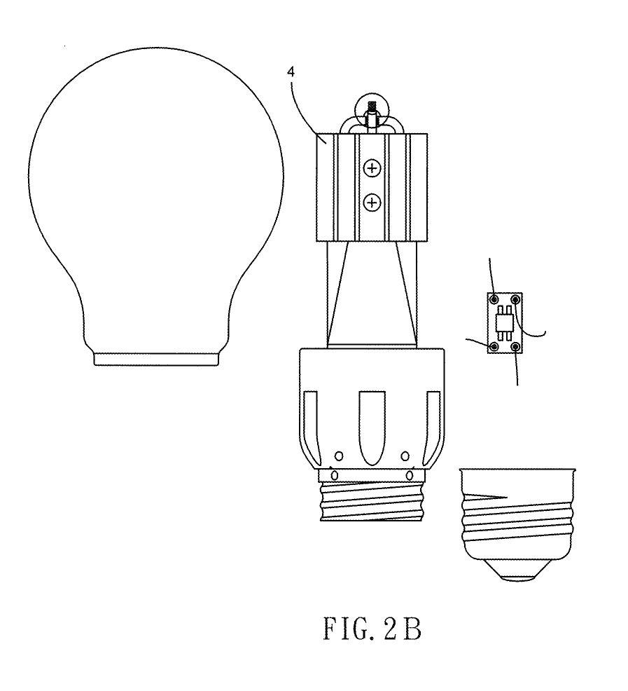

FIGS. 2A and 2B are schematic diagrams of the illumination apparatus according to the third preferred embodiment of the invention.

As shown in FIGS. 2A and 2B, the illumination apparatus of the third preferred embodiment is distinguished from the second preferred embodiment by having an additional metallic heat-sink device 4 screwed to the thermal conductive portion 11 of the body 1. However, the metallic heat-sink device 4 may be fastened to the thermal conductive portion 11 of the body 1 by other suitable technical means. By virtue of this structural arrangement, the heat generated by the light source module 2 can be transferred through the metal rods 14 and the thermal conductive portion 11 of the body 1 to the metallic heat-sink device 4, from which the heat is quickly dissipated to the ambient. The illumination apparatus disclosed herein achieves excellent heat dissipation effect accordingly.

It should be noted that the metallic heat-sink device 4 may be physically connected to the metal rods 14 in a direct or indirect manner, so that both of heat and electric power may be transferred efficiently.

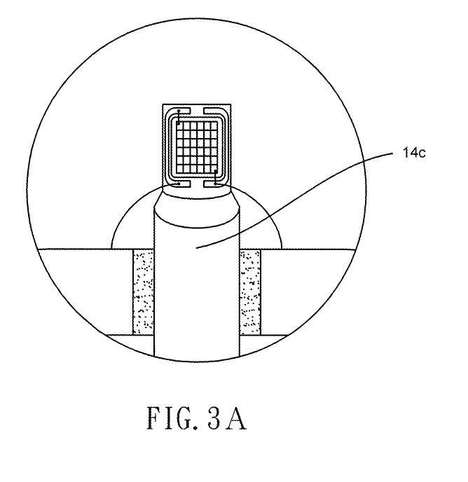

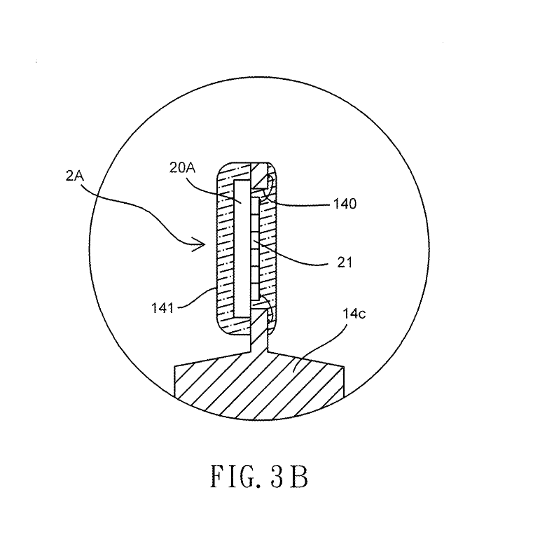

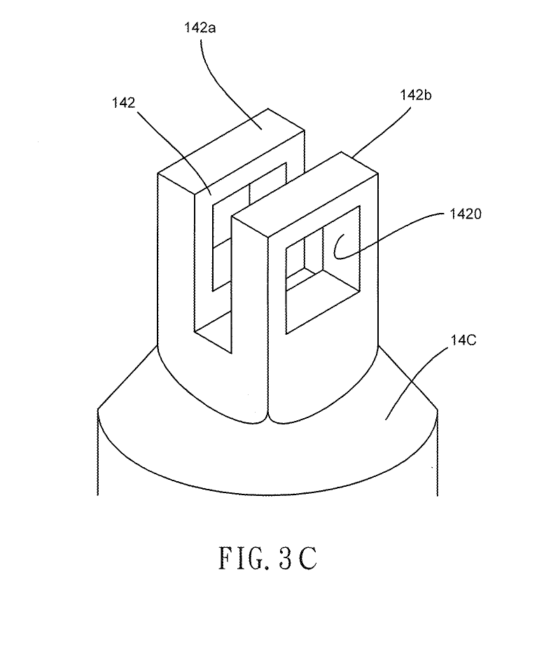

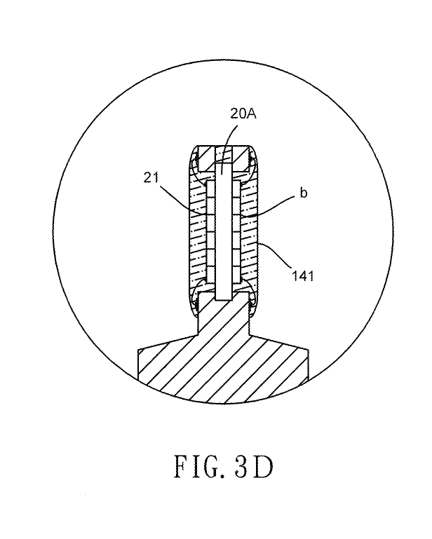

FIGS. 3A and 3B show an alternative example of the light source module used in the invented illumination apparatus according to the invention.

According to the embodiment shown in FIGS. 3A and 3B, the end portion of the metal rod 14c that protrudes outwardly from top of the thermal conductive portion 11 is formed with a via hole 140. The light source module 2A comprises a support plate 20 having high heat dissipation capability. In this embodiment, the support plate 20A is made of transparent material having high heat dissipation capability, such as sapphire and quartz. However, the support plate 20A may be made from any other suitable material.

An LED chip array of multiple LED chips 21 is operatively mounted on the chip-mounting surface of the support plate 20A. The support plate 20A is mounted at the end portion of the metal rod 14c formed with the via hole 140, through which the LED chips 21 mounted on the support plate 20A are exposed.

The end portion of the metal rod 14c where the support plate 20A is mounted is encapsulated by a transparent layer 141 made of insulative transparent material doped with phosphor powder. The transparent layer 141 is coated on the chip-mounting surface of the support plate 20A and the back surface opposite to the chip-mounting surface, so that the LED chips 21 are embedded.

According to the embodiment disclosed herein, the insulative transparent material of which the transparent layer 141 is made is doped with phosphor powder.

It should be noted that the LED chip array described herein is similar to those described in the previous embodiments and comprises a number of LED chips arranged into an M×N matrix, where M and N are independently a natural number of equal to or greater than 1. As such, the LED chips 21 are preferably 6V-480V high-voltage chips connected in series and/or in parallel. The LED chip array may be directly fabricated on a wafer and configured into a predetermined matrix during the wafer dicing process.

It should be noted that in the case where the LED chip array is fabricated into a predetermined matrix during the wafer dicing process, the support plate 20A may be omitted.

FIGS. 3C and 3D show an alternative example of the light source module shown in FIGS. 3A and 3B.

According to the embodiment shown in FIGS. 3C and 3D, the end portion of the metal rod 14c that protrudes outwardly from top of the thermal conductive portion 11 is formed with an elongated recess 142, thereby constituting two oppositely arranged lugs 142a, 142b. The lugs 142a, 142b are each formed with a through hole 1420, with the through hole 1420 formed on the lug 142a aligning with the through hole 1420 formed on the lug 142b.

The light source module 2A described herein comprises a support plate 20A identical to that shown in FIGS. 3A and 3B. The support plate 20A is mounted within the recess 142, so that the two opposite surfaces of the support plate 20A are partially exposed through the through holes 1420 of the lugs 142a, 142b.

The portions of the two opposite surfaces of the support plate 20A that are exposed through the through holes 1420 of the lugs 142a, 142b are operatively provided with an LED chip array of multiple LED chips 21, respectively. Similar to those used in the embodiments above, the LED chips 21 are preferably 6V-480V high-voltage chips connected in series and/or in parallel. The LED chip arrays may be directly fabricated on a wafer and configured into predetermined matrices during the wafer dicing process.

The recess 142 and the through hole 1420 are filled with a transparent layer 141 made of insulative transparent material doped with phosphor powder, so that the support plate 20A and the LED chips 21 are embedded within the transparent layer 141.

It should be noted that the support plate 20A, in addition to having the two opposite surfaces provided with LED chip arrays as described above, includes another three surfaces facing outwardly and all of them are available to be operatively mounted with additional LED chip arrays, when necessary.

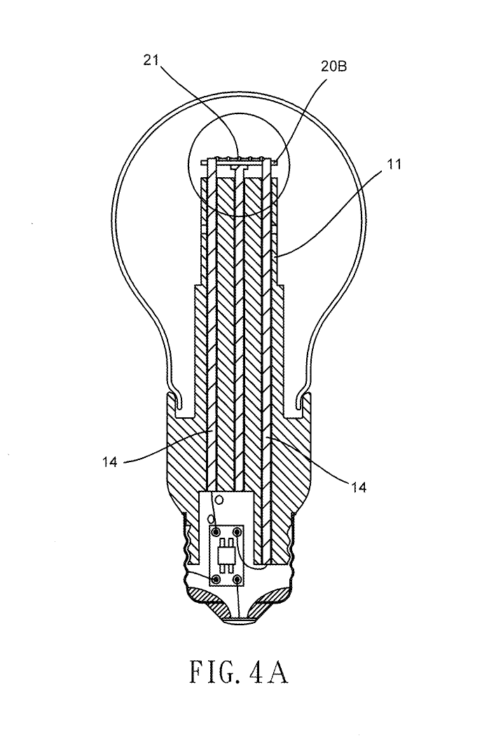

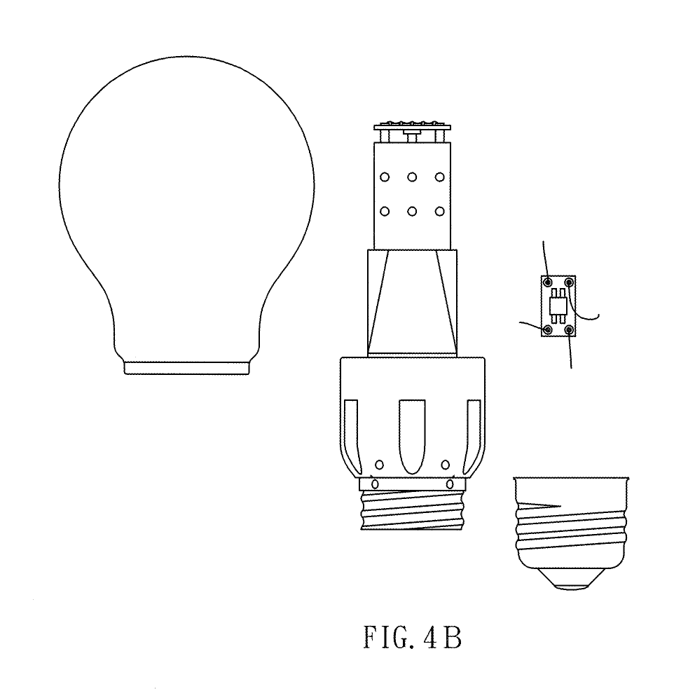

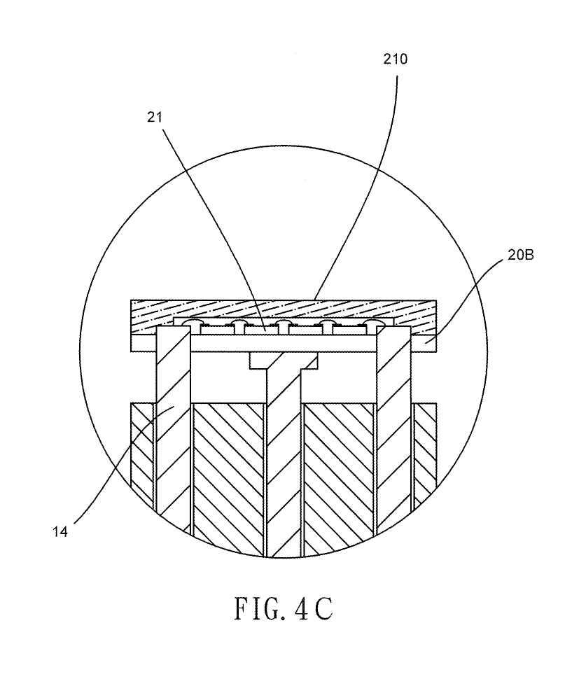

FIGS. 4A and 4B are schematic diagrams of the illumination apparatus according to the fourth preferred embodiment of the invention.

The fourth preferred embodiment is distinguished from the first preferred embodiment in that the light source module according to the fourth preferred embodiment comprises a transparent support plate 20B and an array of LED chips 21 operatively mounted on the support plate 20B.

Preferably, the support plate 20B is identical to the support plate 20A shown in FIGS. 3A and 3B and supported by the end portions of the three metal rods 14 that protrude outwardly from top of the thermal conductive portion 11. The support plate 20B has a chip-mounting surface generally perpendicular to the metal rods 14. As the support plate 20B is made of transparent material, the LED chips 21 can emit light over 360 degree during operation.

It should be noted that the array of LED chips described herein is similar to those described in the previous embodiments and comprises a number of LED chips arranged into an M×N matrix. The LED chip array may be directly fabricated on a wafer and configured into a predetermined matrix during the wafer dicing process.

FIG. 4C is a schematic diagram showing an alternative example of the light source module used in the illumination apparatus according to the third preferred embodiment of the invention.

As shown in FIG. 4C, a transparent cover body 210 having high thermal conductivity is covered on the LED chips 21 and physically connected to the metal rods 14, thereby enhancing the heat dissipation efficiency.

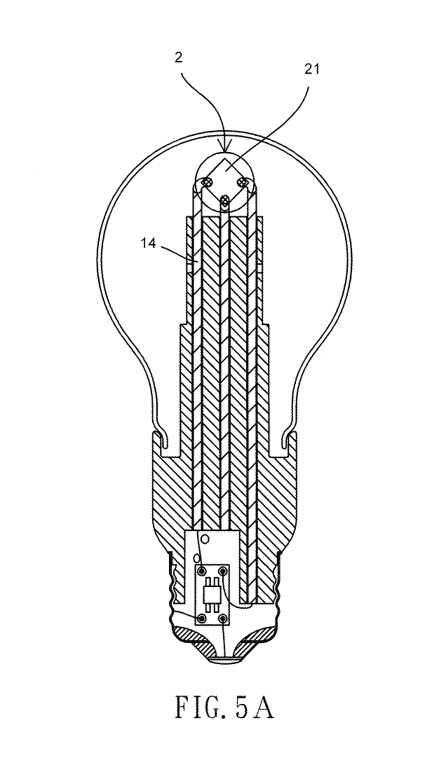

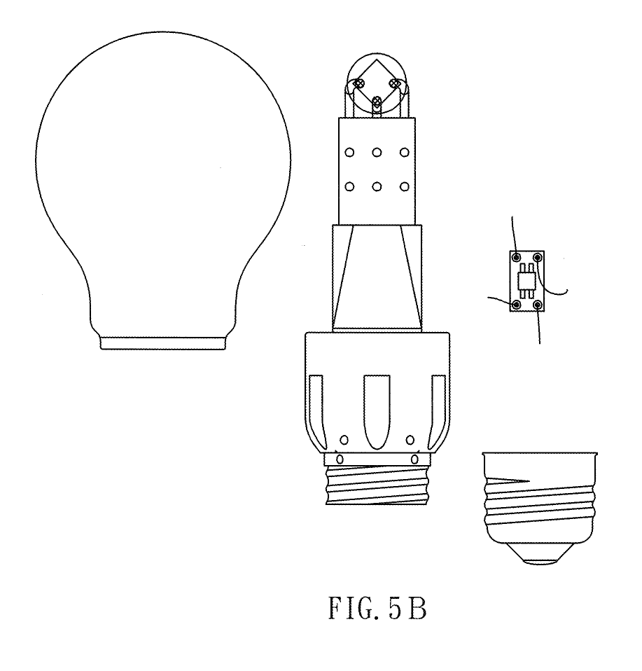

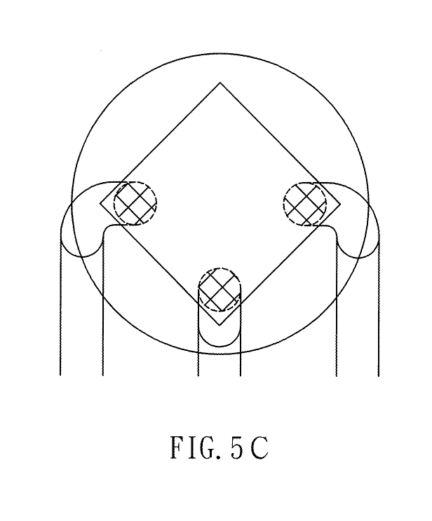

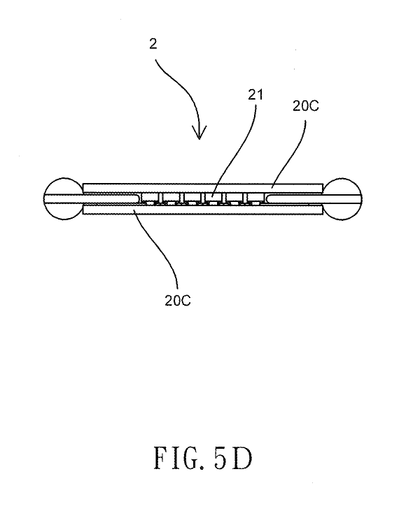

FIGS. 5A to 5C are schematic diagrams of the illumination apparatus according to the fifth preferred embodiment of the invention.

As shown in FIGS. 5A to 5C, the light source module 2 comprises an array of LED chips 21, which are connected in series and/or in parallel during the fabrication and dicing process of an LED wafer (not shown). The predetermined positive and negative electrodes of the respective LED chips 21 in the LED chip array are electrically connected to the corresponding metal rods 14, so that electric power may be transmitted from the power source to the LED chips through the metal rods 14.

FIG. 5D shows an alternative example of the light source module 2 used in the illumination apparatus according to the fifth preferred embodiment of the invention.

As shown in FIG. 5D, the light source module 2 comprises at least two transparent substrates 20C and an array of LED chips 21 operatively disposed between the two substrates 20C and operatively anchored on one of the two transparent substrates 20C. As the respective LED chips 21 in the array are brought in contact with both of the two transparent substrates 20C, the heat generated during the operation of the LED chips 21 can be dissipated rapidly due to the increase in the overall surface area for heat dissipation. Preferably, the transparent substrates 20C may be identical to the support plate 20A shown in FIGS. 3A and 3B.

The array of LED chips 21 may be identical to those described in the embodiments above. In some embodiments, the array comprises separate LED chips 21 operatively mounted on one of the transparent substrates 20C and connected to one another in series and/or in parallel. In the other embodiments, the array may be directly fabricated on an LED wafer (not shown) and configured into a predetermined matrix of multiple LED chips connected in series and/or in parallel during the wafer dicing process.

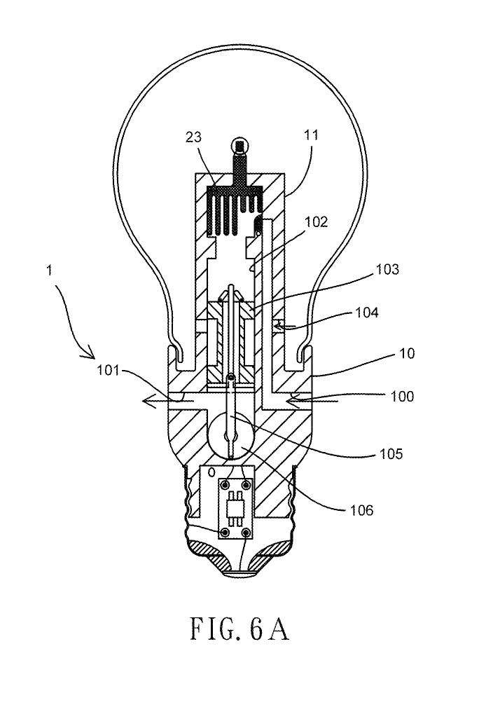

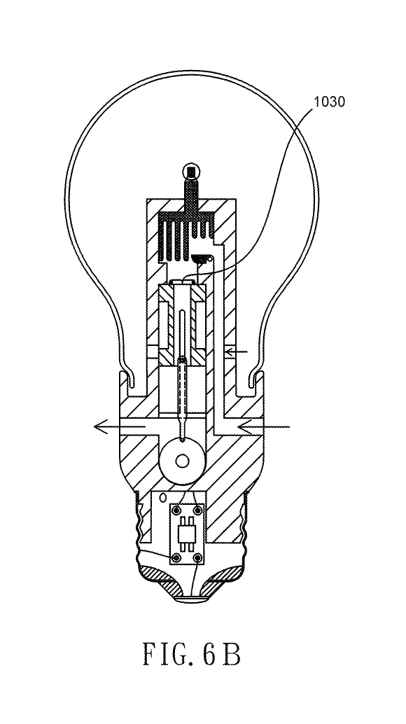

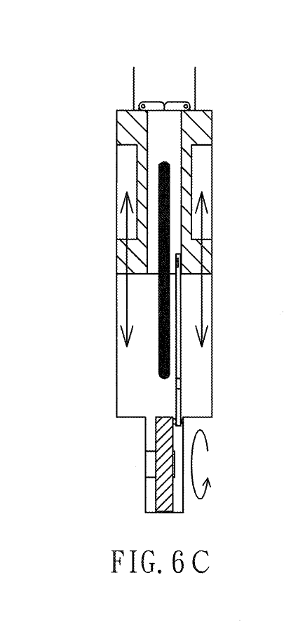

FIGS. 6A to 6C are schematic diagrams of the illumination apparatus according to the sixth preferred embodiment of the invention.

As shown in FIGS. 6A to 6C, the illumination apparatus according to the sixth preferred embodiment further includes a cooling device, which comprises a radially arranged air inlet port 100 formed in the base 10 of the body 1 and connected to the ambient, a radially arranged air outlet port 101 formed in the base 10 of the body 1 and connected to the ambient, and an axial piston passage 102 formed in the base 10 of the body 1 and connected to the ambient and arranged in fluid communication with the inlet port 100 and the outlet port 101. The cooling device further comprises an axially movable piston 103 disposed within the axial piston passage 102, a through hole 104 formed in the thermal conductive portion 11 of the body 1, and a shaft 105 disposed within the axial piston passage 102 and adapted for guiding the piston 103 for reciprocal movement along the axial piston passage 102. The shaft 105 is driven by a roller 106 rotably mounted in the base 10.

It should be noted that the cooling device disclosed herein is designed to operate in a manner similar to that of a Stirling engine.

In this embodiment, the metal rod 14 that provides support for the light source module 2 is mounted with a heat-sink device 16 at its end portion opposite to the end portion where the light source module 2 is located. The heat-sink device 16 is disposed within the passage 102 and remote from the shaft 105.

When the light source module 2 is under operation and the piston 103 is located at a standby position close to the heat-sink device as shown in FIG. 6B, the heat generated by the light source module 2 is transferred into the passage 102 through the heat-sink device. As a result, hot air forces the piston 103 to move along the passage 102 towards where the shaft 105 is linked to the roller 106 and finally arrive at an end position (as shown in FIG. 6A). Meanwhile, the ambient cold air enters the body 1 through the inlet port 100, and the hot air in the housing 3 enters the body 1 via the through hole 104. As the vent 1030 located on top of the piston 103 is opened by the shaft 105, the gas in the body 1 passes through the piston 103 and disperses to the ambient environment via the outlet port 101. The piston 103 returns back to the standby position as the gas departs from the body 1.

By virtue of this structural arrangement, the hot air can be effectively withdrawn from the housing 3, thereby prolonging the service life of the illumination apparatus.

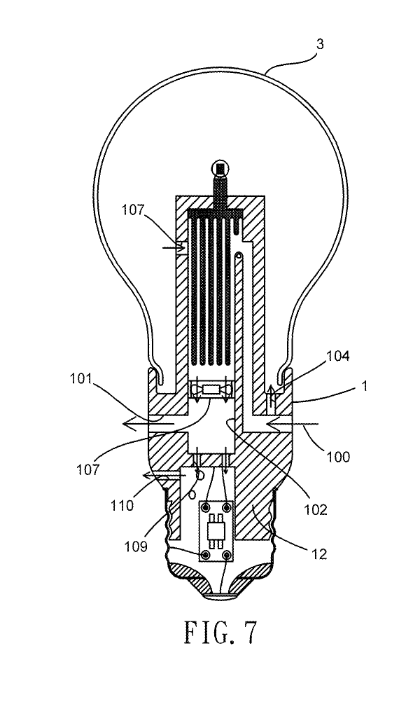

FIG. 7 is a schematic diagram of the illumination apparatus according to the seventh preferred embodiment of the invention.

The seventh preferred embodiment differs from the sixth preferred embodiment in that the piston 103 and the shaft 105 disposed within the passage 102 are replaced with a cooling fan 107 as shown in FIG. 7. When the fan 107 is under operation, the ambient cold air will enter the body 1 through the air inlet port 100. Some of the cold air flows into the housing 3 via the through hole 104 and then enters the passage 102 through the via hole 108 located on the thermal conductive portion 11 and disperses to the ambient through the air outlet port 101.

According to the embodiment disclosed herein, the body 1 further comprises at least one communicating hole 109 disposed in fluid communication with the passage 102 and the threaded portion 12, and at least one vent 110 disposed in fluid communication with the threaded portion 12 and the ambient. When the fan 107 is under operation, the cold air driven by the fan 107 flows through the communicating hole 109 and gets into the threaded portion 12 where the power supply device is disposed, and then flows to the ambient through the vent 110. By virtue of this structural arrangement, the internal temperature of the threaded portion 12 is reduced effectively.

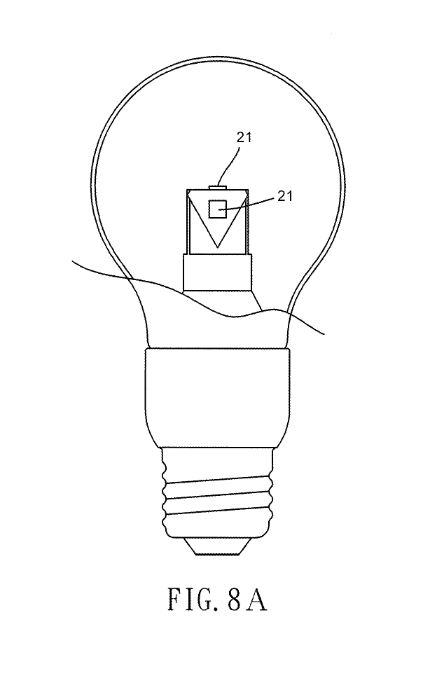

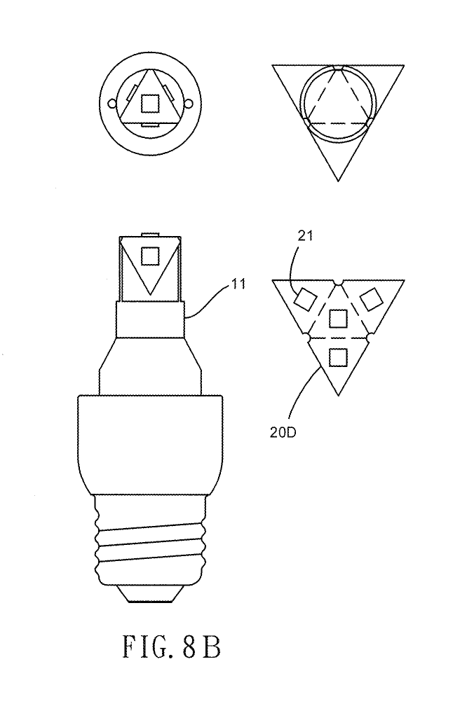

FIGS. 8A and 8B are schematic diagrams of the illumination apparatus according to the eighth preferred embodiment of the invention.

As shown in FIGS. 8A and 8B, the eighth preferred embodiment differs from the first preferred embodiment in that the light source module 2 according to the eighth preferred embodiment comprises a flexible substrate 20D and a plurality of LED chips 21 operatively mounted on the substrate 20D. The flexible substrate 20D is attached to the thermal conductive portion 11 of the body, so that each and every surface of the end portion of the thermal conductive portion 11 is mounted with an LED chip 21.

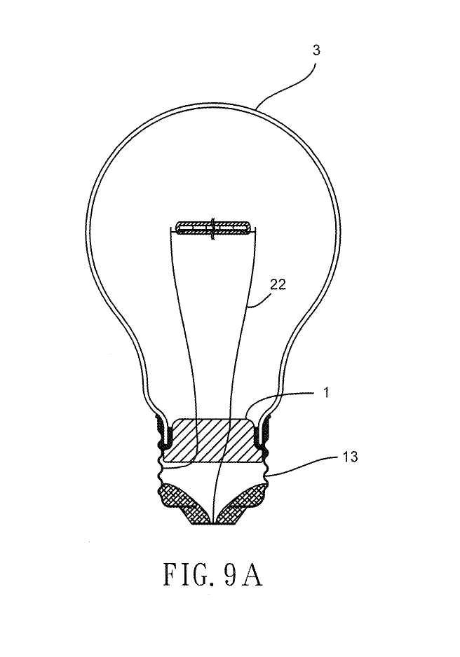

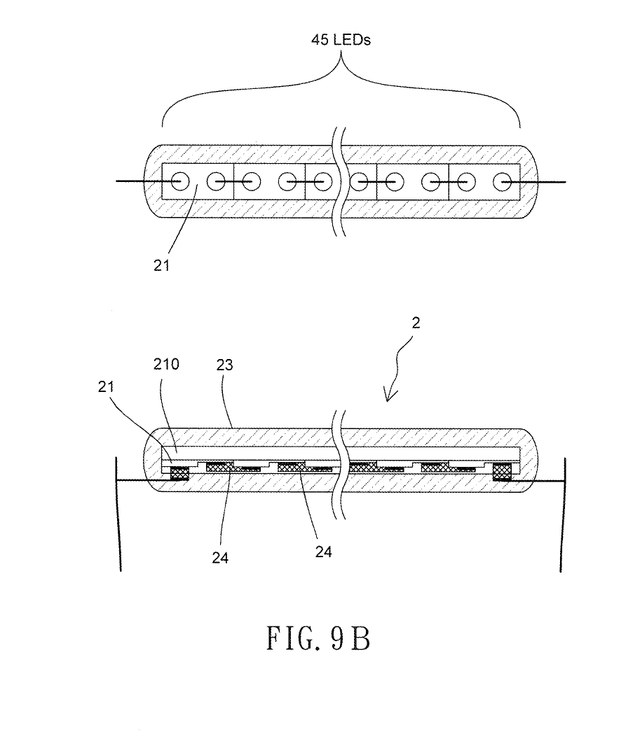

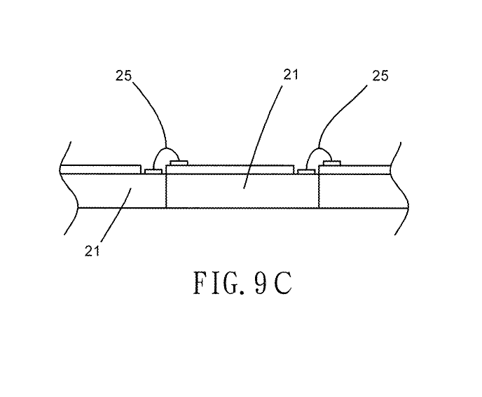

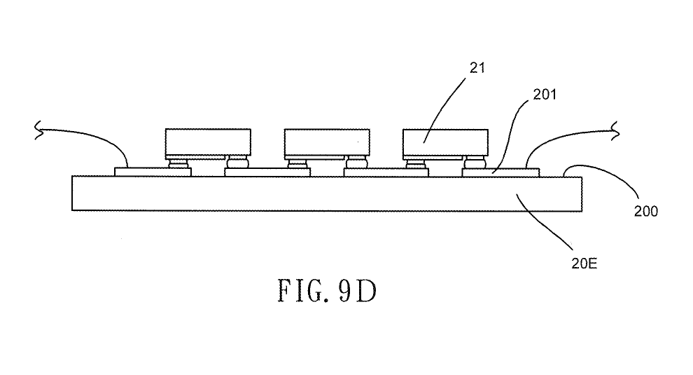

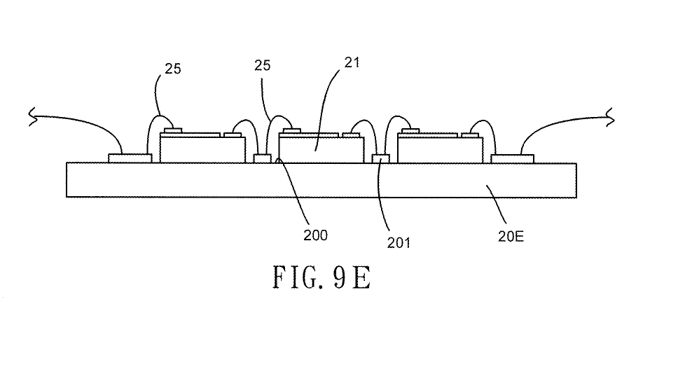

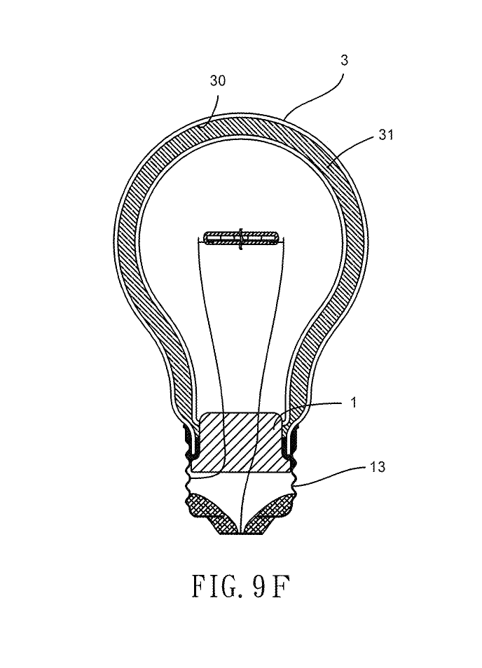

FIGS. 9A and 9B are schematic diagrams of the illumination apparatus according to the ninth preferred embodiment of the invention.

As shown in FIGS. 9A and 9B, the illumination apparatus according to the ninth preferred embodiment comprises a body 1, a standard metallic lamp adaptor 13 coupled to the body 1, a light source module 2 and a transparent housing 3 coupled to the body 1.

The light source module 2 comprises an LED array of LED chips 21 connected in series, a phosphor powder layer 23 encapsulating the LED chips 21, and a pair of conductive wires 22 electrically connected to the LED chips 21 for transmitting electric power to the LED chips.

According to the embodiment disclosed herein, the LED chips 21 have a common transparent base layer 210, which is not subjected to dicing when the LED wafer is diced into individual packages. Except for the first LED chip 21 and the last LED chip 21, each including either an n-type electrode or a p-type electrode not electrically connected to another LED chip in the array, every LED chip 21 in the array has an n- or a p-type electrode electrically connected to the p- or n-type electrode of the immediate upstream LED chip 21 via a conductor 24, and a p- or an n-type electrode electrically connected to the n- or p-type electrode of the immediate downstream LED chip 21 via a conductor 24.

According to the embodiment disclosed herein, the pair of conductive wires 22 are robust enough to hold the LED array in position. Alternatively, the LED array may be carried in position by any other type of structural elements. One of the two conductive wires 22 is electrically connected at its top end to the n- or p-type electrode of the first LED chip 21 in the array, and the other conductive wire 22 is electrically connected at its top end to the p- or n-type electrode of the last LED chip 21 in the array.

The bottom ends of the two conductive wires 22 are electrically connected to an AC power source in a suitable manner. According to the embodiment disclosed herein, the bottom ends of the two conductive wires 22 are electrically connected to the power supplying terminal and the ground terminal of the standard lamp adaptor 13, respectively.

The pair of conductive wires 22 may be configured in the form of miniature heat pipes having high thermal and electrical conductivity or conductive wires coated with a layer of diamond-like carbon (DLC) material having thermal conductivity of from 300 W/mK to 1200 W/mK.

It should be noted that the phosphor powder layer 23 may be identical to those described in R.O.C. Patent No. I364857 and R.O.C. Patent Application No. 098104011, both assigned to the Applicant.

FIG. 9C is a schematic diagram showing an alternative example of the light source module used in the illumination apparatus according to the ninth preferred embodiment of the invention.

According to the alternative example shown in FIG. 9C, the electrical connection between two adjacent LED chips 21 is established by a conductive wire 25.

FIG. 9D is a schematic diagram showing another alternative example of the light source module used in the illumination apparatus according to the ninth preferred embodiment of the invention.

According to the alternative example shown in FIG. 9D, the light source module further comprises a transparent substrate 20E having a circuit-mounting surface 200, on which predetermined circuit traces 201 are formed. The LED chips 21 are separately and operatively flip-chip mounted on the surface 200 of the substrate 20E, so that the LED chips 21 are electrically connected in series and/or in parallel via corresponding circuit traces 201. It should be noted that the surface of the transparent substrate 20E that is opposite to the circuit-mounting surface 200 may also be formed with predetermined circuit traces and mounted with LED chips electrically connected to the predetermined circuit traces.

FIG. 9E is a schematic diagram showing another alternative example of the light source module used in the illumination apparatus according to the ninth preferred embodiment of the invention.

According to the alternative example shown in FIG. 9E, the light source module further comprises a transparent substrate 20E having a circuit-mounting surface 200, on which predetermined circuit traces 201 are formed. The LED chips 21 are separately mounted on the circuit-mounting surface 200 of the substrate 20E, so that the LED chips 21 are electrically connected in series and/or in parallel via corresponding circuit traces 201. It should be noted that the surface of the transparent substrate 20E that is opposite to the circuit-mounting surface 200 may also be formed with predetermined circuit traces and mounted with LED chips electrically connected to the predetermined circuit traces.

FIG. 9F shows an alternative example of the transparent housing used in the illumination apparatus according to the ninth preferred embodiment of the invention.

As shown in FIG. 9F, the housing 3′ comprises a shell 30 jacketed with thermal conductive material 31. The thermal conductive material 31 is disposed in contact with the body 1, thereby enhancing heat dissipation efficiency.

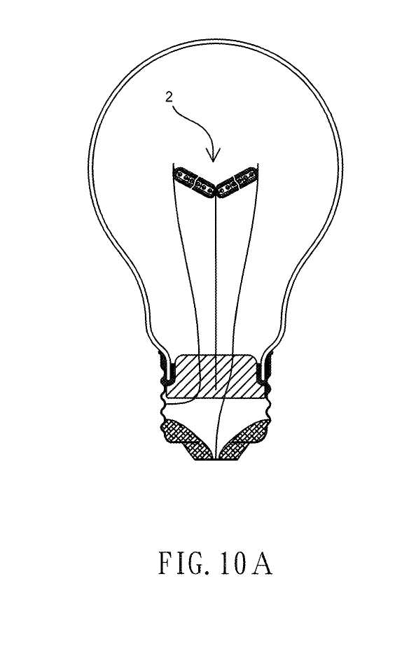

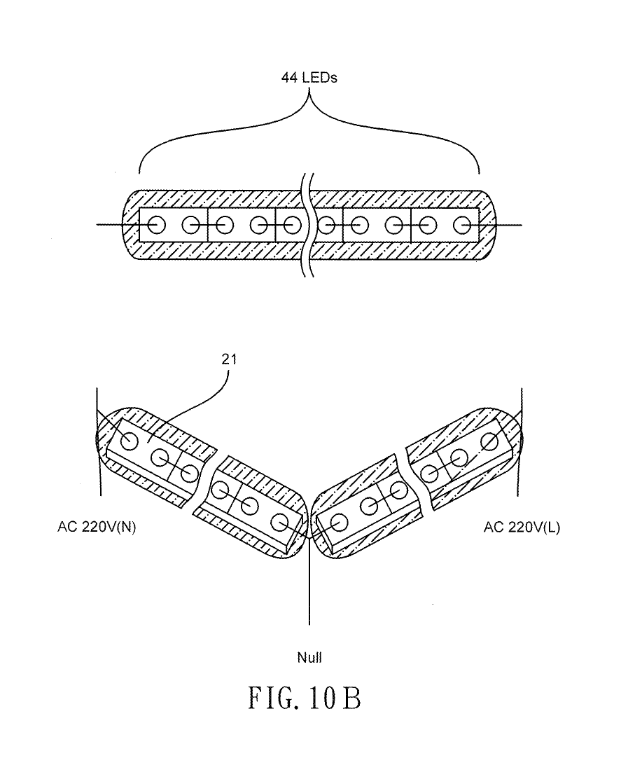

FIGS. 10A and 10B are schematic diagrams of the illumination apparatus according to the tenth preferred embodiment of the invention.

As shown in FIGS. 10A and 10B, the tenth preferred embodiment is distinguished from the ninth preferred embodiment in that the light source module 2 according to the tenth preferred embodiment includes two LED chip arrays described in the ninth preferred embodiment above. According to the embodiment disclosed herein, the two arrays of LED chips 21 are connected in series.

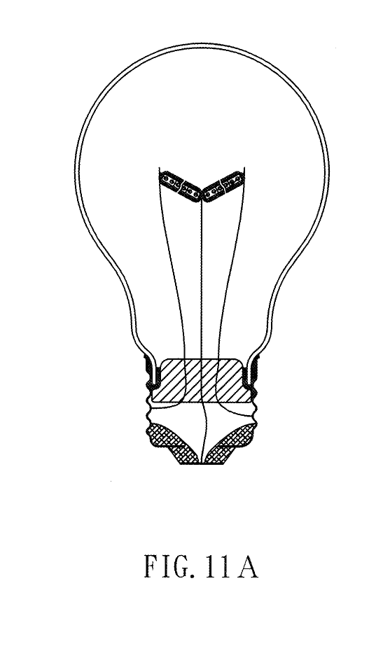

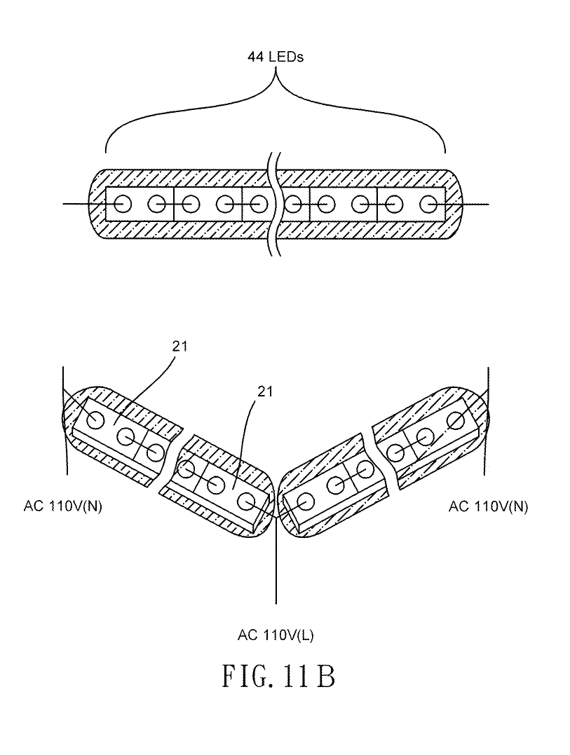

FIGS. 11A and 11B are schematic diagrams showing an alternative example of the illumination apparatus according to the tenth preferred embodiment of the invention.

The embodiment shown in FIGS. 11A and 11B is distinguished from the tenth preferred embodiment in having two arrays of LED chips 21 connected in parallel.

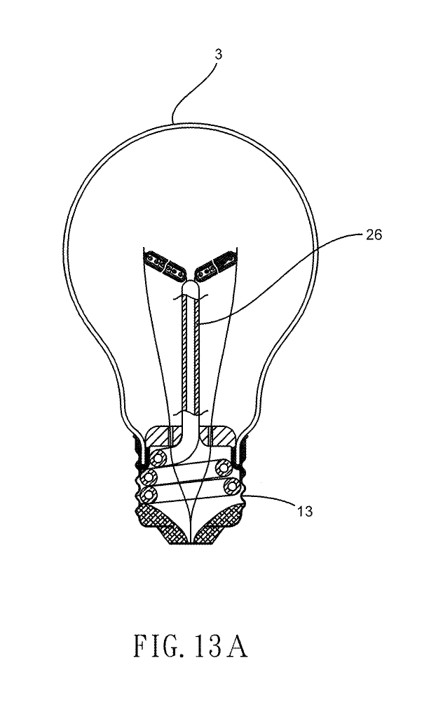

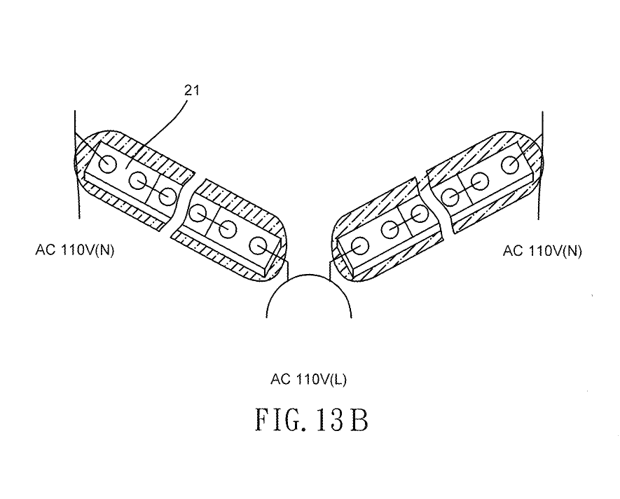

FIGS. 13A and 13B are schematic diagrams showing an alternative example of the illumination apparatus shown in FIGS. 11A and 11B.

As shown in FIGS. 13A and 13B, a heat pipe 26 having high thermal and electrical conductivity includes a top portion electrically connected to the arrays of LED chips 21 and a bottom portion electrically connected to the ground terminal of the adaptor 13. It should be noted that the bottom portion of the heat pipe 26 is wound along the inner wall of the adaptor 13, so that the contact area between the heat pipe 26 and the adaptor 13 is maximized to increase the heat dissipation efficiency. It should be further noted that the heat pipe 26 is provided to efficiently transfer heat from the heat-generating chamber where the LED chips 21 are located (namely, the interior of the housing 3) to a non-heat source chamber where there is no LED chip disposed (namely, the interior of the adaptor 13). Heat is then dissipated to the ambient through the adaptor 13.

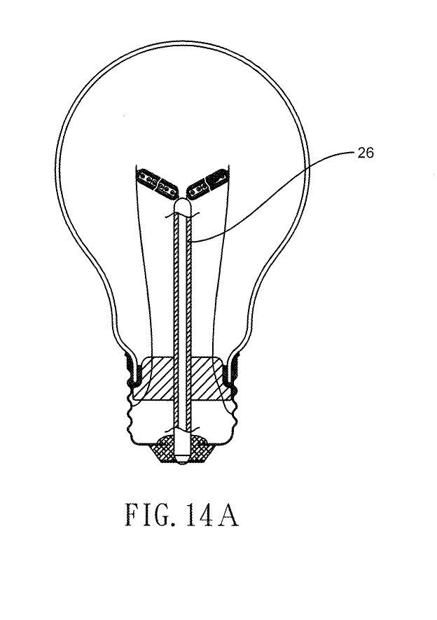

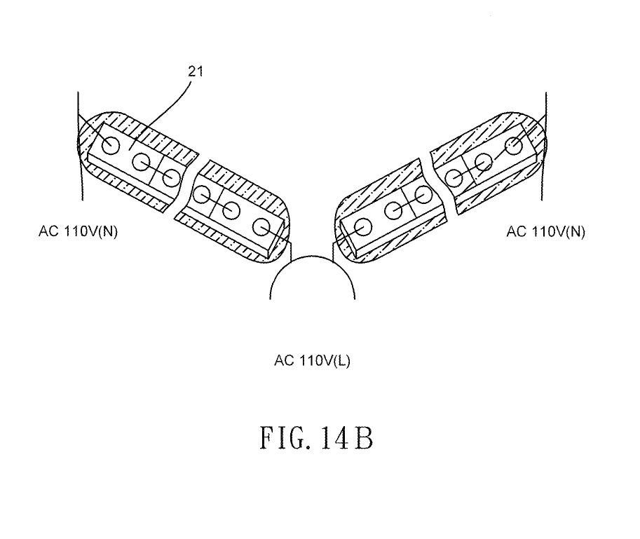

FIGS. 14A and 14B are schematic diagrams showing an alternative example of the illumination apparatus shown in FIGS. 11A and 11B.

As shown in FIGS. 14A and 14B, a heat pipe 26 having high thermal and electrical conductivity includes a top portion electrically connected to the arrays of LED chips 21 and a bottom portion electrically connected to the power supplying terminal of the adaptor 13.

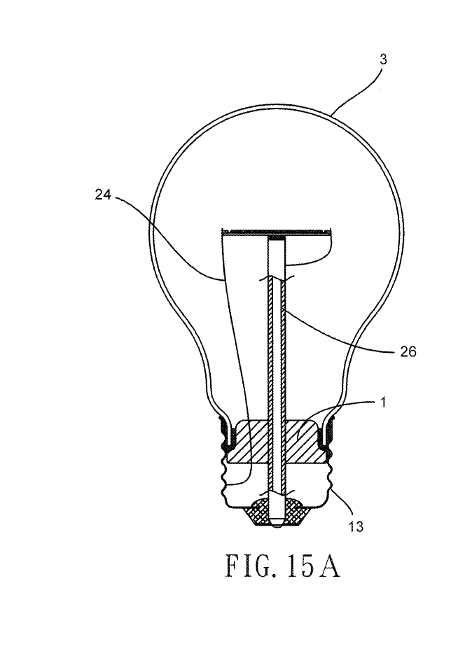

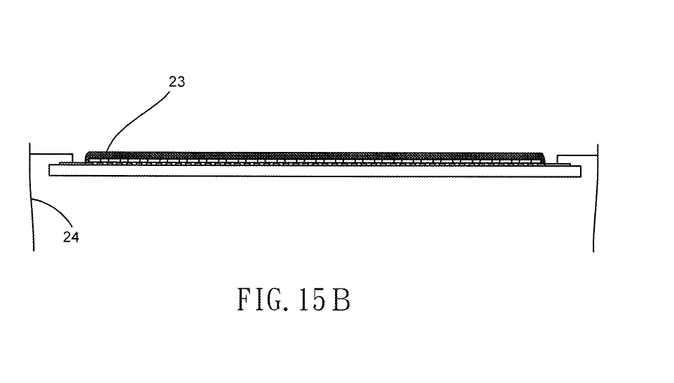

FIGS. 15A and 15B are schematic diagrams of the illumination apparatus according to the eleventh preferred embodiment of the invention.

As shown in FIGS. 15A and 15B, the illumination apparatus according to this embodiment comprises a body 1, a standard metallic lamp adaptor 13 coupled to the body 1, a light source module 2 and a transparent housing 3 coupled to the body 1.

The light source module 2 comprises a heat pipe 26 having high thermal and electrical conductivity, a substrate 20F, a plurality of LED chips 21 operatively mounted on the transparent substrate 20F, a phosphor powder layer 23 encapsulating the LED chips 21, and a pair of conductive wires 22 electrically connected to the LED chips 21 for transmitting electric power to the LED chips 21.

The substrate 20F is mounted on the top portion of the heat pipe 26. The heat pipe 26 includes a bottom portion extending to the adaptor 13 and electrically connected to the power supplying terminal of the adapter 13.

One of the two conductive wires 22 is electrically connected to the heat pipe 26, and the other conductive wire 22 is electrically connected to the ground terminal of the adaptor 13.

It should be noted that the surface of the substrate 20F that is opposite to the surface where the LED chips 21 described above are mounted may also be mounted with additional LED chips.

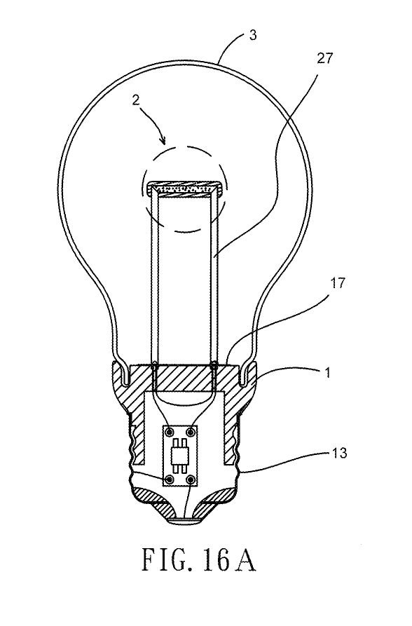

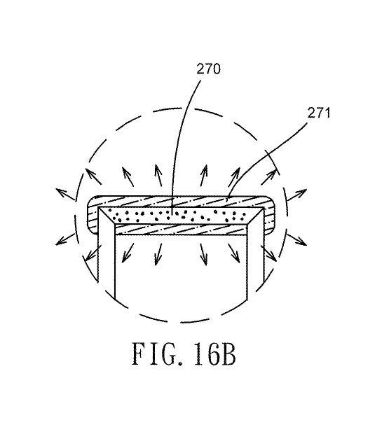

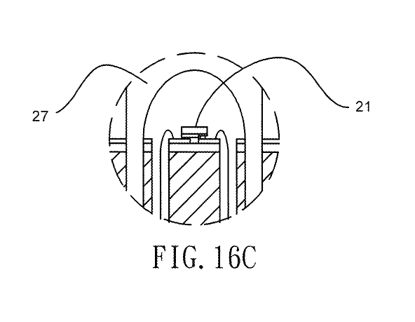

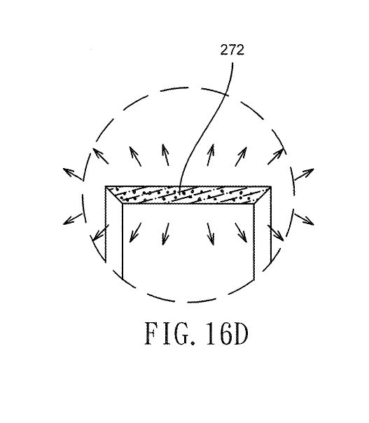

FIGS. 16A to 16C are schematic diagrams of the illumination apparatus according to the twelfth preferred embodiment of the invention.

As shown in FIGS. 16A to 16C, the illumination apparatus according to the twelfth preferred embodiment comprises a body 1 having a base and a threaded portion extending downwardly from the base, a standard metallic lamp adaptor 13 coupled to the threaded portion of the body 1, a light source module 2, and a transparent housing 3 coupled atop the body 1.

The body 1 includes an upper surface 17. The light source module 2 comprises a plurality of LED chips 21 operatively mounted on the upper surface 17. As illustrated, two LED chips 21 are mounted on the upper surface 17. The light source module 2 further comprises a generally U-shaped light guide tube 27. The light guide tube 27 is disposed in such a manner that the primary light emitting surfaces of the LED chips 21 are registered with the corresponding vertical light guide portions of the light guide tube 27. As a result, the light emitted from the LED chips 21 will enter into the vertical light guide portions of the light guide tube 27 and then travel towards the horizontal light guide portion of the light guide tube 27 that bridges the two vertical light guide portions.

According to the embodiment disclosed herein, the horizontal light guide portion of the light guide tube 27 is formed inside with minute gas bubbles 270, so that the light beams traveling in the horizontal light guide portion of the light guide tube 27, when striking the minute gas bubbles 270, will be deflected towards the phosphor powder layer 271 coated on the outer surface of the horizontal light guide portion, causing phosphor to emit light having the desired color.

FIG. 16D is a schematic diagram showing another aspect of the light source module 2 used in the illumination apparatus according to the twelfth preferred embodiment of the invention.

The embodiment of FIG. 16D differs from the embodiment of FIG. 16C in that the horizontal light guide portion of the light guide tube 27 show in FIG. 16D is formed inside with phosphor particles 272 in place of the gas bubbles and the phosphor powder layer shown in FIG. 16C.

In conclusion, the illumination apparatuses disclosed herein can surely achieve the intended objects and effects of the invention by virtue of the structural arrangements and operating steps described above.

While the invention has been described with reference to the preferred embodiments above, it should be recognized that the preferred embodiments are given for the purpose of illustration only and are not intended to limit the scope of the present invention and that various modifications and changes, which will be apparent to those skilled in the relevant art, may be made without departing from the spirit of the invention and the scope thereof as defined in the appended claims.

What is claimed is:

1. An illumination apparatus, comprising:
a body having a lower portion coupled to a standard metallic lamp adaptor and an upper portion;
a light source module comprising a light-emitting diode (LED) array of LED chips connected in series, a phosphor powder layer encapsulating the LED chips, and a pair of conductive wires electrically connected to the LED chips for transmitting electric power to the LED chips; and
a transparent housing coupled to the upper portion of the body, so that the LED chips are enveloped within the transparent housing.

2. The illumination apparatus according to claim 1, wherein the LED chips comprise a common transparent base layer, which is not diced during LED wafer dicing process, and wherein each of the LED chip is connected in series to an adjacent one of the LED chips via a conductor.

3. The illumination apparatus according to claim 2, wherein one conductive wire in the pair of conductive wires is electrically connected at its top end to either an n-type or a p-type electrode of the first LED chip in the LED array, whereas the other conductive wire in the pair of conductive wires is electrically connected at its top end to either a p-type or an n-type electrode of the last LED chip in the LED array, and wherein the pair of conductive wires are electrically connected at their bottom ends to a power supplying terminal and a ground terminal of the standard metallic lamp adaptor, respectively, and wherein the pair of conductive wires are robust enough to hold the LED chips in position within the housing.

4. The illumination apparatus according to claim 3, wherein the pair of conductive wires are configured in the form of miniature heat pipes having high thermal and electrical conductivity, or in the form of conductive wires coated with a layer of diamond-like carbon (DLC) material having thermal conductivity of from 300 W/mK to 1200 W/mK.

5. The illumination apparatus according to claim 2, wherein the conductor for establishing electrical connection between adjacent LED chips is a conductive wire.

6. The illumination apparatus according to claim 2, wherein the conductor for establishing electrical connection between adjacent LED chips is a metallic conductor formed by sputtering, electroplating or any other suitable process.

7. The illumination apparatus according to claim 1, wherein the housing comprises a shell jacketed with thermal conductive material, and wherein the thermal conductive material is disposed in contact with the body, thereby enhancing heat dissipation efficiency.

8. An illumination apparatus, comprising:
a body having a lower portion coupled to a standard metallic lamp adaptor and an upper portion;
a light source module comprising a transparent substrate having a circuit-mounting surface, on which predetermined circuit traces are formed, a plurality of LED chips operatively mounted on the substrate and electrically connected to the circuit traces corresponding thereto, a phosphor powder layer encapsulating the LED chips and the substrate, and a pair of conductive wires electrically connected to the circuit traces corresponding thereto for transmitting electric power to the LED chips; and
a transparent housing coupled to the upper portion of the body, so that the LED chips are enveloped within the transparent housing.

9. The illumination apparatus according to claim 8, wherein the LED chips are operatively flip-chip mounted on the substrate and connected to one another in series.

10. The illumination apparatus according to claim 8, wherein the pair of conductive wires are configured in the form of miniature heat pipes having high thermal and electrical conductivity, or in the form of conductive wires coated with a layer of diamond-like carbon (DLC) material having thermal conductivity of from 300 W/mK to 1200 W/mK.

11. The illumination apparatus according to claim 8, wherein the LED chips are mounted on the substrate and wire-bonded to one another in series.

12. The illumination apparatus according to claim 9, wherein one conductive wire in the pair of conductive wires is electrically connected at its top end to either an n-type or a p-type electrode of the first LED chip in the LED array, whereas the other conductive wire in the pair of conductive wires is electrically connected at its top end to either a p-type or an n-type electrode of the last LED chip in the LED array, and wherein the pair of conductive wires are electrically connected at their bottom ends to a power supplying terminal and a ground terminal of the standard metallic lamp adaptor, respectively, and wherein the pair of conductive wires are robust enough to hold the LED chips in position within the housing.

13. The illumination apparatus according to claim 1, wherein the light source module further comprises an additional LED array of LED chips connected in series, with the two LED arrays being electrically connected in series or in parallel.

14. The illumination apparatus according to claim 8, wherein the light source module further comprises an additional transparent substrate having a circuit-mounting surface, on which predetermined circuit traces are formed, a plurality of LED chips operatively mounted on the additional substrate and electrically connected to the circuit traces corresponding thereto, and a phosphor powder layer encapsulating the LED chips and the additional substrate, and wherein the LED chips mounted on the two substrates are electrically connected in series or in parallel.

15. The illumination apparatus according to claim 13, further comprising a heat pipe having high thermal and electrical conductivity, wherein the heat pipe comprises a top portion electrically connected to the LED chips and a bottom portion electrically connected to the ground terminal of the adaptor, and wherein the bottom portion of the heat pipe is wound along an inner wall of the adaptor, so that the contact area between the heat pipe and the adaptor is maximized to increase heat dissipation efficiency.

16. The illumination apparatus according to claim 13, further comprising a heat pipe having high thermal and electrical conductivity, wherein the heat pipe comprises a top portion electrically connected to the LED chips and a bottom portion electrically connected to the power supplying terminal of the adaptor.

17. The illumination apparatus according to claim 8, wherein the housing comprises a shell jacketed with thermal conductive material, and wherein the thermal conductive material is disposed in contact with the body, thereby enhancing heat dissipation efficiency.

18. The illumination apparatus according to claim 11, wherein one conductive wire in the pair of conductive wires is electrically connected at its top end to either an n-type or a p-type electrode of the first LED chip in the LED array, whereas the other conductive wire in the pair of conductive wires is electrically connected at its top end to either a p-type or an n-type electrode of the last LED chip in the LED array, and wherein the pair of conductive wires are electrically connected at their bottom ends to a power supplying terminal and a ground terminal of the standard metallic lamp adaptor, respectively, and wherein the pair of conductive wires are robust enough to hold the LED chips in position within the housing.

19. The illumination apparatus according to claim 14, further comprising a heat pipe having high thermal and electrical conductivity, wherein the heat pipe comprises a top portion electrically connected to the LED chips and a bottom portion electrically connected to the ground terminal of the adaptor, and wherein the bottom portion of the heat pipe is wound along an inner wall of the adaptor, so that the contact area between the heat pipe and the adaptor is maximized to increase heat dissipation efficiency.

20. The illumination apparatus according to claim 14, further comprising a heat pipe having high thermal and electrical conductivity, wherein the heat pipe comprises a top portion electrically connected to the LED chips and a bottom portion electrically connected to the power supplying terminal of the adaptor.

21. An illumination apparatus, comprising:
a body;
a standard metallic lamp adaptor coupled to the body;
a light source module comprising a heat pipe having high thermal and electrical conductivity, a substrate, a plurality of LED chips operatively mounted on the transparent substrate, a phosphor powder layer encapsulating the LED chips, and a pair of conductive wires electrically connected to the LED chips for transmitting electric power to the LED chips, wherein the heat pipe comprises a top portion mounted with the substrate and a bottom portion extending to the adaptor and electrically connected to the power supplying terminal of the adapter, and wherein one conductive wire in the pair of conductive wires is electrically connected to the heat pipe, and the other conductive wire in the pair of conductive wires is electrically connected to the ground terminal of the adaptor; and
a transparent housing coupled to the body, so that the LED chips are enveloped within the transparent housing.

22. An illumination apparatus, comprising:
a body having a base, a threaded portion extending downwardly from the base and an upper surface;
a standard metallic lamp adaptor coupled to the threaded portion of the body;
a light source module comprising a plurality of LED chips operatively mounted on the upper surface of the body and further comprising a generally U-shaped light guide tube having vertical light guide portions bridged by a horizontal light guide portion, the light guide tube being disposed such that primary light emitting surfaces of the LED chips are registered with the corresponding vertical light guide portions of the light guide tube, thereby making a first light beam emitted from the LED chips enter into the vertical light guide portions of the light guide tube and then travel towards the horizontal light guide portion of the light guide tube, wherein the horizontal light guide portion of the light guide tube is formed inside with minute gas bubbles, so that the first light beam, when striking the minute gas bubbles, is deflected towards a phosphor powder layer coated on an outer surface of the horizontal light guide portion, causing the phosphor powder layer to emit a second light beam having the desired color; and
a transparent housing coupled to the body, so that the LED chips are enveloped within the transparent housing.

23. An illumination apparatus, comprising:
a body having a base, a threaded portion extending downwardly from the base and an upper surface;
a standard metallic lamp adaptor coupled to the threaded portion of the body;
a light source module comprising a plurality of LED chips operatively mounted on the upper surface of the body and further comprising a generally U-shaped light guide tube having vertical light guide portions bridged by a horizontal light guide portion, the light guide tube being disposed such that primary light emitting surfaces of the LED chips are registered with the corresponding vertical light guide portions of the light guide tube, thereby making a first light beam emitted from the LED chips enter into the vertical light guide portions of the light guide tube and then travel towards the horizontal light guide portion of the light guide tube, wherein the horizontal light guide portion of the light guide tube is provided inside with phosphor particles, so that the first light beam, when striking the phosphor particles, causing the phosphor particles to emit a second light beam having the desired color and the second light beam is deflected towards an outer surface of the horizontal light guide portion; and
a transparent housing coupled to the body, so that the LED chips are enveloped within the transparent housing.
